(19) United States
(12) Patent Application Publication
(10) Pub. No.: US 2003/0051662 A1
(43) Pub. Date: Mar. 20, 2003

(54) Thermal reactor for transport polymerization of low epsilon thin film

(75) Inventors: Chung J. Lee, Fremont, CA (US); Oanh Nguyen, Union City, CA (US); Atul Kumar, Fremont, CA (US)

Correspondence Address: T. Ling Chwang, Suite 600, 2435 N. Central Expressway, Richardson, TX, 75080, US

(73) Assignee: DIELECTRIC SYSTEMS, INC., Fremont, CA (US)

(21) Appl. No.: 10/141,358

(22) Filed: May 8, 2002

Related U.S. Application Data
(63) Continuation-in-part of application No. 10/126,919, filed on Apr. 19, 2002.
Application No. 10/126,919 is a continuation-in-part of application No. 10/125,626, filed on Apr. 18, 2002.
Application No. 10/125,626 is a continuation-in-part of application No. 10/115,879, filed on Apr. 4, 2002.
Application No. 10/115,879 is a continuation-in-part of application No. 10/116,724, filed on Apr. 4, 2002.
Application No. 10/116,724 is a continuation-in-part of application No. 10/029,373, filed on Dec. 20, 2001.
Application No. 10/029,373 is a continuation-in-part of application No. 10/028,198, filed on Dec. 20, 2001.
Application No. 10/028,198 is a continuation-in-part of application No. 09/925,712, filed on Aug. 9, 2001.
Application No. 09/925,712 is a continuation-in-part of application No. 09/795,217, filed on Feb. 26, 2001.

(51) Int. Cl. C23C 14/00

(52) U.S. Cl. 118/50

(57) ABSTRACT

An improved reactor to facilitate new precursor chemistries and transport polymerization processes that are useful for preparations of low ∈ (dielectric constant) films. An improved TP Reactor that consists of UV source and a fractionation device for chemicals is provided to generate useful reactive intermediates from precursors. The reactor is useful for the deposition system.

### RELATED APPLICATION

This application is a continuation-in-part of the Lee et al., U.S. patent application, Ser. No. 10/126,919, entitled “Process Modules for Transport Polymerization of Low ∈ Thin Films,” and filed on Apr. 19, 1002. The Ser. No. 10/126,919 application is a continuation-in-part of the Lee et al., U.S. patent application, Ser. No. 10/125,626, entitled “Multi-Stage-Heating Thermal Reactor for Transport Polymerization,” and filed on Apr. 17, 2002. The Ser. No. 10/125,626 application is a continuation-in-part of the Lee et al., U.S. patent application, Ser. No. 10/115,879, entitled “UV Reactor for Transport Polymerization,” and filed on Apr. 4, 2002. The Ser. No. 10/115,879 application is a continuation-in-part of the Lee et al., U.S. patent application, Ser. No. 10/116,724, entitled “Chemically and Electrically Stabilized Polymer Films,” and filed on Apr. 4, 2002. The Ser. No. 10/116,724 application is a continuation-in-part of the Lee et al., U.S. patent application, Ser. No. 10/029,373, entitled “Dielectric Thin Films from Fluorinated Benzocyclobutane Precursors,” and filed on Dec. 19, 2001. The Ser. No. 10/029,373 application is a continuation-in-part of the Lee et al., U.S. patent application, Ser. No. 10/028,198, entitled “Dielectric Thin Films from Fluorinated Precursors,” and filed on Dec. 19, 2001. The Ser. No. 10/028,198 application is a continuation-in-part of the Lee et al., U.S. patent application, Ser. No. 09/925,712, entitled “Stabilized Polymer Film and its Manufacture,” and filed on Aug. 9, 2001. The Ser. No.09/925,712 application is a continuation-in-part of the Lee et al., U.S. patent application, Ser. No. 09/795,217, entitled “Integration of Low ∈ Thin films and Ta into Cu Dual Damascene,” and filed on Feb. 26, 2001. The entirety of each of the applications or patents listed above is hereby specifically incorporated by reference.

### BACKGROUND

This invention is related to semiconductor equipment that is useful for the fabrication of integrated circuits (“IC”). More specifically, this invention is related to a Thermal Reactor for a transport polymerization (“TP”) process module, wherein the process module is useful for the deposition of low dielectric (“∈”) thin films in IC manufacture. The Thermal Reactor has a very high surface-to-volume ratio, which makes it very compact. The Thermal reactor also has in-situ cleaning capacity, which makes it suitable for use in the process module system disclosed in the co-pending patent application, entitled “Process Modules for Transport Polymerization of Low ∈ thin films,” with a Ser. No. 10/126,919. This co-pending application was filed with the USPTO on Apr. 19, 2002 with Lee et al. listed as inventors, and is hereby incorporated by reference.

As a consequence of shrinking IC device geometries, an increase in capacitance has been observed on interconnects, which can result in unacceptable cross talk and resistance-capacitance (“RC”) delay. This RC delay has become a serious problem for ICs with feature size of less than 0.18 μm. Thus, the dielectric constant of the current insulation materials from which IC's are constructed must be decreased to meet the needs for fabrication of future ICs. In addition to dielectric and conducting layers, the “barrier layer” may include metals such as Ti, Ta, W, and Co and their nitrides and silicides, such as TiN, TaN, TaSixNy, TiSixNy, WNx, CoNx and CoSiNx. Ta is currently the most useful barrier layer material for the fabrication of IC's that currently use copper as conductor. The “cap-layer” or “etch-stop-layer” normally consists of dielectric materials such as SiC, SiN, SiON, SiyOx and its fluorinated silicon oxide (“FSG”), SiCOH, and SiCH. Thus, the new dielectric materials must also withstand many other manufacturing processes following their deposition onto a substrate.

Currently, there are two groups of low ∈ dielectric materials, which include a traditional inorganic group, exemplified by SiO₂, its fluorine doped product, FSG and its C & H doped products, SiOₓC_{y}H_{z} and newer organic polymers, exemplified by SiLK, from Dow Chemical Company. Chemical Vapor Deposition (“CVD”) and spin-on coating method have been used to deposit, respectively, the inorganic and polymer dielectric films. These current dielectric materials used in the manufacturing of the ICs have already proven to be inadequate in several ways for their continued use in mass production of the future IC's. For example, these materials have high dielectric constants (∈≧2.7), they have low yield (<5-7%) and marginal rigidity (Young's Modulus less than 4 GPa). In light of the shortcomings of current dielectric materials, a director of a major dielectric supplier has suggested that the use of thin films with high dielectric constants (e.g. ∈=3.5) will be extended to the current 130 nm devices (A. E. Brun, “100 nm: The Undiscovered Country”, Semiconductor International, February 2000, p79). This statement suggests that the current dielectric thin films are at least four years behind the Semiconductor Industrial Association's (“SIA”) road map. The present lack of qualified low dielectric materials now threatens to derail the continued shrinkage of future IC's.

Currently, all conventional CVD processes have failed to make useful ∈<2.7, Ta-compatible thin films. Due to many unique advantages that will be revealed in the following sections, we believe that TP soon will emerge as a primary CVD approach for fabrications of future IC's. Some of the important chemistries and mechanisms involved during TP has been reviewed previously (Chung Lee, “Transport Polymerization of Gaseous Intermediates and Polymer Crystals Growth” J. Macromol. Sci-Rev. Macromol. Chem., C16 (1), 79-127 (1977-78), pp79-127, and is hereby incorporated by reference).

Conventional CVD Processes:

There are several fundamental differences between the TP and conventional CVD processes. First, in all traditional CVD processes, starting chemicals are introduced into a CVD chamber where the “feed chemicals” are subjected to needed energy sources such as plasma or ozone to generate reacting intermediates. Film will grow when these intermediates impinge onto a substrate such as a wafer. Second, in these CVD processes, wafer is normally heated and a CVD chamber is normally operated under sub-atmosphere pressure or moderate vacuum in the ranges of few mTorrs to few Torrs. Third, in these CVD processes, film not only grows on wafer but also on chamber wall. Fourth, conventional CVD processes using ozone oxidative processes are not suitable for making organic thin films. Fifth, current CVD dielectrics that are prepared from plasma polymerization of Organo-Siloxanes have ∈ of about 2.7 or higher.

Plasma polymerization of organic precursors can provide ∈ of lower than 2.7, however, they inherit many drawbacks, which include:

1. Due to poorly selective cracking of chemical bonds by plasma, some feed chemicals can end up with several reactive sites but others still have none during plasma polymerization. To avoid this disparity by increasing power levels for instance, films with highly cross-linked density and high residual stress would result.

2. During plasma polymerization, free radicals, anions, and ions with various reactive sites on each intermediate will be generated. Since intermediates with different molecular orbital configurations likely will not react with each other, some of these intermediates will have no chance to react and become a part of the resulting network. Due to this inherent complexity, plasma polymerization commonly results in poor yield (few percent) and films with different chemical structures at molecular levels.

3. Since all kinds of reactive intermediates, including very corrosive fluorine ion or radical could be generated, it is also desirable to heat the substrate, so condensation of low molecular weight products, corrosive species and not reacted impurities can be avoided. However, with presence of corrosive species such as fluorine ion, corrosion of underlying metal such as a barrier metal on wafer can become a serious problem when wafer is kept at high temperatures.

4. In addition, when more than 15 to 20 molar % of multi-functional intermediates consisting of more than two reactive sites are present inside chamber, most of these reactive sites will be trapped inside the polymer networks or become chain ends. Post annealing is done under controlled reductive or hydrogen atmosphere before the film is removed from vacuum chamber. This is needed to eliminate these reactive chain ends in order to avoid later reactions of these reactive chain ends with undesirable chemicals such as water or oxygen.

5. Finally, presence of many polymer chain-ends and pending short chains in polymer networks will result in high dielectric loss, thus the resulting dielectric will not be useful for high frequency (GHz) applications that are critical to most future IC applications.

For the reasons listed above, all conventional CVD processes have failed to make useful ∈<2.7, Ta-compatible thin films.

The State of Transport Polymerization:

Transport polymerization (“TP”) employs known chemical processes to generate desirable reactive intermediates among other chemical species. Chemical processes that are particularly useful for this invention include photolysis and thermolysis. These two chemical processes can generate useful reactive intermediates such as carbenes, benzynes and other types of diradicals using appropriate precursors.

Photolysis can be accomplished by irradiation of compounds using electrons, UV or X-ray. However, high energetic electron and X-ray sources are expensive and typically not practical for reactors useful for this invention. When a UV photolytic process is used, a precursor that bears special leaving groups is normally required. For example, reactive intermediates such as carbenes and diradicals can be generated by the UV photolysis of precursors that bear ketene or diazo groups. However, these types of precursors normally are expensive and not practical to use due to their very unstable nature at ambient temperatures. Other precursors and chemistry have been used for generating reactive intermediates and discussed in prior art (C. J. Lee, “Transport Polymerization of Gaseous Intermediates and Polymer Crystals Growth”J. Macromol. Sci-Rev. Macromol. Chem., C16 (1), 79-127 (1977-78), pp79-127). However, most of these precursors are quite expensive to prepare and are not readily available, thus they are not desirable nor practical for IC fabrications outlined in the current invention. In the co-pending application with a Ser. No. 10/115,879, entitled “UV reactor for transport polymerization” a specially designed UV Reactor is used for Transport Polymerization and thin film preparation of some thermally stable precursors. This co-pending application was filed with the USPTO on Apr. 4, 2002, with Lee et al. listed as inventors and is hereby incorporated by reference.

Thermolysis has been used for TP of poly (Para-Xylylenes) (“PPX”) for the coating of circuit boards and other electronic components since early 1970s. Currently, all commercial PPX films are prepared by the Gorham method (Gorham et al., U.S. Pat. No. 3,342,754, the content of which is hereby incorporated by reference). The Gorham method employed dimer precursor (I) that cracks under high temperatures (e.g. 600 to 680° C.) to generate a reactive and gaseous diradical (II) under vacuum. When adsorbed onto cold solid surfaces, the diradical (II) polymerizes to form a polymer film (III).

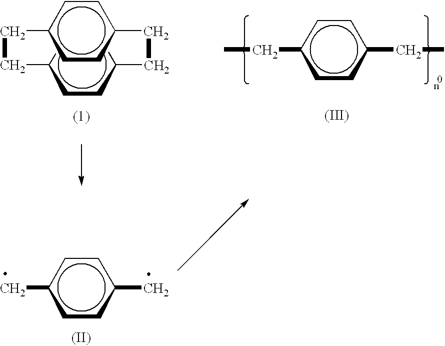

Since 1970, several commercialized products have appeared on the market with similar chemical structures. For example, a polymer PPX-D {—CH₂—C₆ H₂Cl₂—CH₂—} had a dielectric constants, ∈ of 3.2 However, all these polymers were not thermally stable at temperatures higher than 300 to 350° C., and were not useful for fabrications of future ICs that require dielectric with lower ∈ and better thermal stability. On the other hand, the PPX-F,—(CF₂—C₆H₄—CF₂—)_{N} has a ∈=2.23 and is thermally stable up to 450° C. over 2.5 hours in vacuum. Therefore, rigorous attempts have been made to make PPX-F from dimer (—CF₂—C₆H₄—CF₂—)₂ (Wary et al, Proceedings, 2nd Intl. DUMIC, 1996 pp207-213; ibid, Semiconductor Int'l, 19(6), 1996, p211-216) using commercially available equipment. However, these efforts were abandoned due to high cost of the dimer and incompatibility of the barrier metal (e.g. Ta) with PPX-F films prepared by TP (Lu et al, J.Mater.Res.Vol,14(1), p246-250, 1999; Plano et al, MRS Symp.Proc.Vol.476, p213-218, 1998—these cited articles are herby incorporated by reference.)

Many commercial thermal reactors have been available for deposition of PPX since early 1970. These deposition systems comprise of primarily the same four main components, as shown in the prior art 100 in FIG. 1: a sample holder and material delivery system 105 is in fluid communication with the reactor 120 through a needle valve 110. The deposition chamber 130 is in fluid communication with the reactor 120 and the cold trap 140. Additionally, the entire system is connected to a vacuum system.

In these thermal reactors, a resistive heater and a stainless steel reactor (i.e. pyrolyzer) are used to crack dimers. Additionally, a tubular quartz reactor has been used to crack the dimer (e.g. {—CH₂—C₆H₄—CH₂—}₂ as shown above in equation (I)), and used for making PPX-N (Wunderlich et al, Jour. Polymer. Sci. Polymer. Phys. Ed., Vol. 11, (1973), pp 2403-2411; ibid, Vol. 13, (1975), pp1925-1938). It is important to note that the PPX-N dimer (e.g. {—CH₂—C₆H₄—CH₂—}₂) bears no halogen, and thus there was no potential corrosion of the stainless steel reactor during preparation of PPX-N. In other words, a stainless steel pyrolyzer can only be used for a dimer that has halogens on a Sp²C carbon to make PPX-D ({—CH₂—C₆ H₂Cl₂—CH₂—}, but it is not compatible with a precursor consisting of halogens on the Sp³C, for example, a precursor such as formula (IV) of the following:

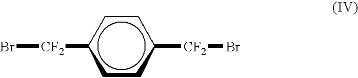

When (IV) is used, the iron inside the pyrolyzer's surfaces can react with the bromine if the temperature inside the pyrolyzer is higher than 420 to 450° C. The resulting iron bromide would contaminate the dielectric film and make it unsuitable for IC fabrications. Other shortcomings of commercial PM's are that they are not equipped with a proper deposition chamber for wafer or a vapor controller, which are important to the current invention. Thus, these commercial process modules are not useful for the present invention that uses halogen-containing precursors.

U.S. Pat. No. 5,268,202 with Moore listed as inventor (“the Moore '202 Patent”), teaches that a dibromo-monomer (e.g. IV={Br—CF₂—C₆Cl₄—CF₂—Br}) and a metallic “catalyst” (Cu or Zn) inside a stainless steel pyrolyzer can be used to generate reactive free radical (V) according to the reaction (3). However, to lower the cost of starting materials, a large proportion (>85 to 95 molar %) of a more readily available co-monomer with structure {CF₃—C₆H₄—CF₃} has also been used to make PPX-F.

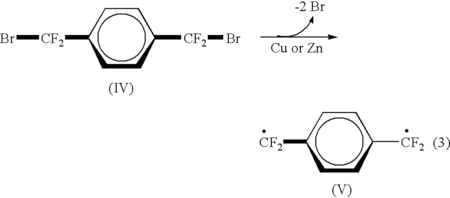

There are several key points that need to be addressed concerning the usage of the monomer (IV) in reaction (3). First, an earlier U.S. Pat. No. 3,268,599 (“the Chow '599 Patent”) with Chow listed as inventor, revealed the chemistry to prepare a dimmer as early as 1966. However, the Chow '599 Patent only taught the method to prepared dimer {CF₂—C₆H₄—CF₂}₂ by trapping the diradical (V) in a solvent. Furthermore, the equipment and processing methods of the Chow '599 Patent employed were not suitable for making thin films that are useful for IC fabrications. Second, according to the Moore '202 Patent, the above reaction (3) would need a cracking temperature ranging from 660-680° C., without using the “catalysts”. However, we found that metallic “catalysts” such as Zn or Cu would readily react with organic bromine at temperatures ranging from 300 to 450° C., the pyrolyzer temperatures employed by the Moore '202 Patent. Formation of metallic halides on surfaces of these “catalysts” would quickly deactivate these “catalysts” and inhibit further de-bromination shown in reaction (3). In addition, the presence of Zn and Cu halides inside a pyrolyzer would likely cause contamination for the process module and dielectric films on wafer. Third, cooling of reactive intermediate and wafer cooling could not be efficient because both the wafer holder and pyrolyzer were located inside a close system for the deposition chamber that was used in the Moore '202 Patent. Consequently, the process module used by the Moore '202 Patent cannot be useful for preparation of thin films of this invention.

### SUMMARY

This invention is related to semiconductor equipment that is useful for the fabrication of integrated circuits (“IC”). More specifically, this invention relates to a Thermal Reactor for a transport polymerization (“TP”) process module, wherein the process module is useful for the deposition of low dielectric (“∈”) thin films in IC manufacture. One aspect of the thermal reactor comprises its construction which utilizes a vacuum vessel with a precursor-gas-inlet for receiving the precursor, a reactor cleaning subsystem (“RCS”) inlet on the vacuum vessel for receiving a cleaning gas, and a gas-outlet for discharging an intermediate from the thermal reactor. The thermal reactor also comprises a thermal source for cracking the precursor material and a heater body within the vacuum vessel to transfer energy to the precursor material. The thermal reactor temperature can maintain a stable temperature in a range of about 300° C. to about 700° C. A thermal couple and an insulation jacket surrounding the thermal reactor are used to help regulate the temperature of the thermal reactor. The vacuum vessel can either be constructed from UV transparent materials or ceramic materials and has an inside heater body capable of maintaining uniform temperatures that range from about 300° C. to 700° C. inside the vacuum vessel. The thermal source is selected from a group comprising an infrared heater, an irradiation heater, a thermal heater, a plasma heater, a resistive heater and a microwave heater. The vacuum vessel has an internal volume that ranges in size but is at least 20 cm³, preferably 40 cm³ for coating wafers of 200 mm with one μm thickness of low dielectric thin film. The Thermal Reactor has a very high surface-to-volume ratio, which makes it very compact. For example, the heater body has a total surface area of at least 300 cm², preferably at least 500 cm² for coating a 200 mm wafer with one μm thickness of low dielectric thin film.

Another aspect of the current invention is the arrangement of the heater body inside the thermal reactor. For example, the heater body comprises a plurality of alternating heating zones and mixing zones wherein the alternating heating zones have a spiral orientation. The alternating heating zones may comprise multiple heating fins to increase the heating efficiency. The heater body may also comprises a plurality of rows and columns of alternating heater fins or comprise spherical closely packed balls (“CPB”), wherein the multiple heating fins, alternation rows and columns of fins or CPB's are spaced at a distance less than the mean free path (“MFP”) of a gas in a given heating zone. Alternately, the heater body comprises a plurality of alternating heating elements and mixing zones, and wherein the alternating heating elements are on a standoff of the heater body arranged in a spiral configuration relative to a direction of overall flow from gaseous precursors in the thermal reactor. It is important to note that the alternating heating elements are manufactured from materials resistant to halogen corrosion at temperatures in a range of 300° C.-700° C. Examples of alternating heating elements consists of porous ceramic disks, ceramic disks with small holes, or ceramic fins

Another aspect of the current invention is that the thermal reactor was designed for precursor material with a following general chemical structure:

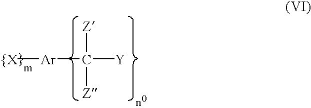

wherein: n⁰ or m is individually zero or an integer, and (n⁰+m) comprises an integer of at least 2 but no more than a total number of sp²C—X substitution on the aromatic-group-moiety (“Ar”), Z′ and Z″ are similar or different, and X and Y are leaving groups. However, the TP processing of such materials may leave an organic residue inside the thermal reactor. Thus, another aspect of the current invention is a method to clean the thermal reactor using a reactor cleaning subsystem (“RCS”). The method for cleaning the reactor with the RCS comprises: heating the heater body to a desired temperature with an energy source; introducing a heated gas into the thermal reactor through the RCS gas inlet; burning the organic residue with the heated gas to give an oxidized gas; and discharging the oxidized gas from the reactor. During the cleaning process the inside temperature of the thermal reactor is at least 400° C. The heated gas supply is maintained at a temperature within at least 100° C. of a temperature in the thermal reactor to prevent thermal shock or cracking of the heater bodies inside the thermal reactor. The heated gas supply used to clean the thermal reactor is pressurized air or oxygen, in the range from about 1 to 20 psi.

### BRIEF DESCRIPTION OF THE DRAWINGS

FIG. 1 shows the four main components of a conventional deposition system for transport polymerization;

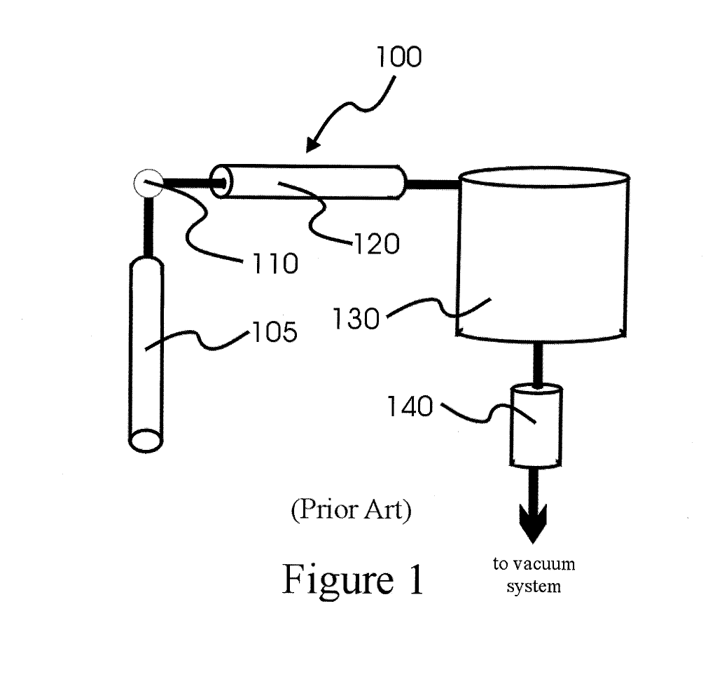

FIG. 2 shows an illustration of a single wall reactor;

FIG. 3 shows a double-wall quartz tube that can be used in conjunction with both an inner and outer IR heater;

FIG. 4 shows a cross-section of a cone-shaped heater body with a center hole for an inner IR heater;

FIG. 5 shows a 3-dimensional cross-sectional view of a double all quartz tube with porous heating bodies.

### DETAILED DESCRIPTION OF PREFERRED EMBODIMENTS

Chemical and Engineer Principles: Instead of using a conventional tubular stainless steel pyrolyzer, the preferred embodiment of the present invention requires a specially designed Thermal reactor that facilitates new precursor chemistries and deposition processes used to prepare low ∈ thin films. The Thermal reactor needs to generate useful reactive intermediates with high efficiency and low side-reaction product from precursors that have a general chemical structure as shown in formula (VI).

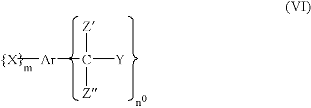

wherein, n⁰ or m are individually zero or an integer, and (n⁰+m) comprises an integer of at least 2 but no more than a total number of sp²C—X substitution on the aromatic-group-moiety (“Ar”). Ar is an aromatic or a fluorinated-aromatic group moiety. Z′ and Z″ are similar or different, and individually a hydrogen, a fluorine, an alkyl group, a fluorinated alkyl group, a phenyl group or a fluorinated phenyl group. X is a leaving group, and individually a —COOH, —I, —NR₂, —N⁺R₃, —SR, —SO₂R, wherein R is an alkyl, a fluorinated alkyl, aromatic or fluorinated aromatic group, and Y is a leaving group, and individually a —Cl, —Br, —I, —NR₂, —N⁺R₃, —SR, —SO₂R, or —OR, wherein R is an alkyl, a fluorinated alkyl, aromatic or fluorinated aromatic group. Furthermore, the aromatic is preferably a fluorinated aromatic moiety including, but not limiting to, the phenyl moiety, —C₆H₄₋ₙFₙ (n=0 to 4) such as —C₆H₄— and —C₆F₄—; the naphthenyl moiety, —C₁₀H₆₋ₙFₙ— (n=0 to 6) such as —C₁₀H₆— and —C₁₀F₆—; the di-phenyl moiety, —C₁₂H₈₋ₙFₙ— (n=0 to 8) such as —C₆H₂F₂ —C₆H₂F₂— and —C₆F₄—C₆H₄—; the anthracenyl moiety, —C₁₂H₈-n; the phenanthrenyl moiety, —C₁₄H₈₋ₙFₙ—; the pyrenyl moiety, —C₁₆H₈₋ₙFₙ— and more complex combinations of the phenyl and naphthenyl moieties, —C₁₆H₁₀₋ₙFₙ—. Note that isomers of various fluorine substitutions on the aromatic moieties are also included in this invention.

The functional requirements for a thermal reactor are largely determined by chemical structure of leaving groups X and Y and chemical methods that used to remove them in the thermal reactor. The leaving groups can be removed from precursors of formula (VI) by several different chemical methods. The methods that generate reactive intermediates under vacuum or under inert atmosphere include, but are not limited to:

irradiation using photons or electrons

cracking using thermal heat,

plasma energy, or

microwave energy

In order for a thermal reactor to be useful for this invention, it must generate useful reactive intermediates with high efficiency and have low side reaction products. In essence, the TP Reactor temperature should be closely controlled and the temperature inside the thermal reactor should be uniform versus the flow direction so that only desirable chemical reactions can take place. We found that tubular pyrolyzers that are used in commercial process modules do not meet critical temperature requirements for TP Reactor of this invention. For example, when a tubular pyrolyzer that was 8 inch long and 1.2 inch diameter was heated at 480° C. under 10 mTorrs vacuum, only a small region of the inner wall in the down stream areas reached the desirable 480° C., which was due to poor heat conduction under vacuum. Results from calculations indicated that a large volume inside the pyrolyzer was at temperature far below 480° C. Thus, a tubular reactor does not satisfy the required high efficiency (>99.99%) for removing Br from a precursor of formula (IV) wherein, Y=Br, and the bond energy (“BE”) of the sp³Cα-Br bond equals 58 Kcal/Mole under few mTorrs. In fact, under such a condition, a majority of precursor material would pass through the tubular pyrolyzer without removal of Bromine.

One alternative is to increase the pyrolyzer temperature to 680° C. or higher. At these higher temperatures, the inside temperatures of the pyrolyzer may achieve complete removal of Bromine from the precursor of formula (IV) (wherein Y=Br). However, at such high temperatures (e.g. ≧680° C.), some of the sp²C—H and sp³C—C bonds of the precursor (IV) and intermediates (V) respectively would also be broken. These undesirable reactions would result in formation of multi-functional (>2) radicals and “coke” formation inside the pyrolyzer. The resultant formation of a thick carbon deposit inside the pyrolyzer would further insulate heat conduction to the center region of the pyrolyzer, and would make the pyrolyzer even less effective. In addition, the multi-functional radicals would result in dielectric films consisting of many polymer chain ends. Thus, the resulting films produced in tubular pyrolyzers have poorer thermal stability and inferior electrical properties.

The problems associated with a precursor of formula (IV) (wherein Y=Br) will not occur when conventional dimers are employed. These conventional dimers (e.g. formula (I)) have a high ring-strain-energy (“Eᵣₛ”) of about 31 Kcal/mole due to presence of two bulky benzene rings. The ring strain energy, in principle would lower the BE (76 Kcal/mole) of the sp³Cα-sp³C bonds in the dimers to bonding energy of a leaving group (“BE_{L}”)=76 Kcal/mole minus 31 Kcal/mole, or BE_{L}=45 Kcal/mole and reduce the required temperatures for a tubular pyrolyzer. It is important to note that the next weakest bond in the dimer is the sp³Cα-H bond that has a bonding energy of a core group (“BE_{C}”) of about 88 kcal/mole, or a differential bond energy (“dBE”)=(BE)_{C}−(BE)_{L}=(88−45) or 43 Kcal/mole for this dimer. Therefore, under normal recommend pyrolyzer temperatures ranging from 620° C. to 640° C., the tubular pyrolyzer could provide a near 100% efficiency without apparent coke formation. However, under the identical pyrolyzer temperatures and vacuum conditions, a precursor such as in formula (IV) (wherein Y=Br), generate a large portion of un-reacted precursors that would form a thin film that is useless for IC fabrications.

In short, having a precursor that comprises of an appropriate designed chemical structure and leaving groups is only a necessary first step, but not sufficient for making thin films that are useful for fabrications of future ICs. In addition, a properly designed thermal reactor is needed. Accordingly, design requirements for thermal reactors will be different for desirable precursors that have different chemical structures and leaving groups. When precursors employed for the current invention meet specific criteria, a proper thermal reactor can then be designed accordingly.

Although not wanting to be bound by theory, the bonding energy for a leaving group (BE)_{L} needs to be less than 65 to 70 Kcal/Mole. However, exceptions for this general rule can be found. For example, the ring-strained dimer of formula (I) as mentioned above. Additionally, the thermal removal of a desirable leaving group (e.g. carboxylic group) can occur at temperatures as low as 200 to 250° C. under ambient, and 300 to 400° C. under vacuum. This thermal pyrolysis could occur readily when the carboxylic is in its salt or ionic form, or when its resonant energy can lower the bonding energy of the carboxylic group. In addition, the (BE)_{L} should be at least 25 to 30 Kcal/Mole, preferably 30-40 Kcal/Mole, lower than bonding energy of the 2nd weakest chemical bond that presented in the precursor. For instances, for precursor with formula (IV) (wherein, m=0, n=2 and Y=Br), the BE for the leaving group is (“BE_{L}”)=58 Kcal/Mole, thus Z can be —F ((BE)_{C}=96 Kcal/Mole) and —Ar— can be {—C₆H₄—}. For such a precursor, the dBE is 38 Kcal/Mole, herein dBE=(BE)_{C}−(BE)_{L}. When this precursor is used, the maximum temperature variation across to the gas diffusion direction, (“dTr”) inside the thermal reactor can be as high as 150° C. to 190° C., and preferably no more than 120° C. to 130° C. When a thermal reactor had a dTr larger than 150° C. to 190° C., the resultant films contained impure chemicals that would result if the reactor temperature were too low. Coke formation would occur when a high reactor temperature was used and carbon would degrade the TP Reactor very shortly after deposition.

Although not wanting to be bound by theory, the maximum allowed temperature variation (as expressed in °C.) inside the thermal reactor should be equal to or less than 5 times, preferably 3 to 4 times, of the dBE in Kcal/Mole (i.e. “dTr≦5*dBE”). However, precursors with desirable chemical structures and leaving groups are often not available due to limited available synthetic schemes and starting materials, a thermal Reactor with lower dTr will allow choices for using precursors that have smaller dBE. For example, when inside reactor temperature can be controlled to ±35° C., then precursors of formula (VI) that have m=n=1, Y=Br and I, X=Br and I and Z=F can be useful for this invention.

(11-2) Thermal Reactor Designs: The preferred TP thermal reactor design of the current invention will incorporate the chemical properties of the precursor material. For example, the gas reactor will break up the selected precursors into intermediates and other side products at low pressure. The inside of the thermal reactor is made of high purity materials that are inert to the chemical reactions of the selected precursors and their intermediates. The reactor relies on thermal energy (i.e. temperature) to carry out the reactions. Furthermore, the preferred thermal reactor requires re-activation or cleaning after a specified period of film depositions, which can be accomplished by burning the organic residues inside the reactor in the presence of oxygen. Wherein, oxygen or air is fed through a mass flow controller (“MFC”) and a valve into the thermal reactor. The resulting combustion products (mainly CO, CO₂, H₂O and other small organic compounds) can be pumped directly to the exhaust through the reactor by-pass line and valve. Accordingly, a thermal reactor has an inlet for precursor and an outlet for reaction products that generated from the reactor. In addition, the outlet also has a bypass for injection of oxygen during cleaning and its inlet has a bypass for exhaust of combustion products. Alternatively, a ceramic reactor can be also cleaned using oxidative plasma in conjunction with a plasma-cleaning device.

In a preferred embodiment of this invention, a thermal or photo-assisted thermal cracking process is employed to generate useful reactive intermediates from precursors described in the above. Therefore, a TP thermal reactor is comprised of a heater and an inside heater body for heating the precursor and an outside container for keeping the inside heater body under vacuum condition. Details of the material selection, heating methods, and heater body designs are discussed below. Heater body and heater element can be used as interchangeable terms.

Material Selections: The preferred materials selected for the container wall of the thermal reactor are selected and manufactured from a group of materials including, but not limited to quartz, sapphires or Pyrex glass, Alumina Carbide, Al₂O₃, surface fluorinated Al₂O₃, Silicon Carbide, Silicon Nitride, and preferably Silicon Carbide. These conductive materials are resistant to halogen corrosion at temperatures as high as 680° C. When a container wall is a metallic material, the inside wall of the metallic container needed to be coated with one of the above ceramic material to prevent corrosion. The heater body can be constructed from these ceramic media with pores, small tubes, heating fins or spherical balls.

Heating Methods: The thermal reactor can be heated by several methods. However, in preferred embodiments of the present invention, a resistive heater, and an infrared (“IR”) heater are used. When a resistive heater is used, the inside heater body has physical contact(s) with inside wall of the thermal reactor. The inside heater body is heated primarily via conductance and some radiation. In this case, the heater body needs to have excellent thermal conductivity to maintain uniform temperature inside a vacuum. Without a proper design to take advantage of the radiation effect, the inside heater body will have high temperature variation especially if the heater body has poor conductivity.

In a preferred embodiment of the present invention, radiation provides the energy to heat the heater-bodies inside a vacuum. For example, an infrared (“IR”) heater or microwave can be used for heating the reactor. In U.S. Pat. No. 6,140,456 with Chung Lee et al listed as inventors (“the Lee '456 patent”), IR was used to crack precursors passing inside a vacuum quartz tube. The Lee '456 patent provides teachings that under few mTorrs of vacuum, IR is not effective due to the extremely short residence time of precursors inside the reactor. Additionally the Lee '456 patent utilized microwave energy to generate plasma for transport polymerization. However, as was noted above plasma polymerization is not suitable for making useful low k of this invention.

An IR heater can be used to heat the heater body. Tungsten Halogen lamps are part of a preferred embodiment for an IR heater of the current invention. When an IR heater is utilized, the wall of thermal reactor should use an IR transparent material (e.g. quartz), so that IR can reach the inside heater body. Preferably, the inside heater body is an IR absorbing material such as Alumina Carbide, Alumina Oxide and preferably Silicon Carbide. The heater body consists of heater elements that can be a porous medium, small tubes, fins or spherical balls. These IR adsorbing elements can be placed as continuous media or be spaced inside the reactor, thus create an alternating heating and mixing zones inside the reactor. This type of thermal reactor can generate more uniform heating for passing precursors and prevent back diffusion for intermediates. When an employed precursor exhibits strong absorption in the IR ranges for its leaving groups such as halogen and carboxylic acid, photon-assisted thermal cracking can enhance the reactor efficiency.

Alternatively, a resist heater can be used to heat a black body such as Silicon Carbide so the black body can generate IR in the ranges from 700 to 1200 cm⁻¹. In conjunction, the outside wall of the thermal reactor should be constructed using a IR transparent material so that radiation can reach the inside of the thermal reactor.

As an alternative, the outside wall of the thermal reactor can also be constructed using a material that is not transparent to IR. For instance, the resist heater can be mounted directly onto the wall of the thermal reactor, while a black body such as SiC is inserted inside the thermal reactor. In this case, the black body inside the thermal reactor is heated to generate IR in the ranges from 700 to 1200 cm⁻¹. Thus, the precursor vapor can be heated by the IR radiation inside the reactor.

IR heater can be manufactured from a single heating element of Iron-Chromium-Aluminum or Nickel-Chromium coil. This type of IR heater can ramp up in 10 to 20 second and has up to 60 Watts/in or higher of power; while a double wounded heating coil can ramp up in 5 seconds. In addition, a lamp consists of Tungsten filaments in vacuum or in the presence of Halogen can be used as IR heater for this invention. This type of IR lamp can provide up 60 Watts/in² to 200 Watts/in² or higher of power and can ramp up in 1-2 seconds, but it also needs air or water-cooling to operate. Commercial IR heaters are available for instance from Solar Products Inc. at Pompton Lakes in New Jersey.

Heater Body: Precursors gain thermal energy during heating by colliding with the heating elements or heater bodies inside the thermal reactor. Once a precursor molecule acquires sufficient thermal energy to meet or exceed the energy of activation, thermal cracking or breakage of the chemical bonds occurs. Therefore, before the thermal cracking can occur it is important that the heater body provides a sufficient surface area for the precursors to collide as they are transported through the thermal reactor. Although not wanting to be bound by theory, the required temperature for the heater body decreases as the resident time and/or number of collisions of the precursor increases for a specified precursor feed rate. Furthermore, the resident time of a precursor in the reactor for a given feed rate will increase as the volume of the reactor becomes larger. Thus, by increasing the surface area of the inside heater body, high reactor temperatures and large reactor volumes, can be avoided. Accordingly, a thermal reactor with a lower than desired inside surface area would require excess reactor temperature, which would lead to the formation of undesirable films and excess carbon deposits inside the reactor. Thus, in a preferred embodiment of the present invention, the volume of the thermal reactor is less than 60 cm³, preferably 30 cm³, and the surface area of the heater body is at least 300 cm², preferably 500 cm². Additionally, the reactor should be built to hold a vacuum under 0.01 to 1 mTorr. Several methods can be used to increase the surface areas of the inside heater body, including, but not limited to: a porous medium; small tubes; heating fins; or spherical balls.

A thermal reactor with a lower than desired inside surface area would require excess reactor temperature, thus result in undesirable films and excess carbon formation inside the reactor. The surface areas of the inside heater body can be adjusted by using a porous medium, small tubes, heating fins or spherical balls. To increase the surface area of the heater bodies, porous ceramic materials are used for the present invention.

Ideal porous heater bodies should have skeletal structure and their skeletal wall consist of no void, no inclusion, no entrapment or metallic impurity. The heating elements inside the thermal reactor can be manufactured from materials that have good resistance to chemical corrosion, especially to halogen at temperatures as high as 680° C. These materials include quartz, sapphires or Pyrex glass, Al₂O₃, surface fluorinated Al₂O₃, Silicon Carbide, Silicon Nitride. Porous SiC and Al₂O₃ is preferred.

A porous medium is particularly useful for this invention if it has reticular structure of open, duode-cahedronal-shaped cells connected by continuous solid ceramic ligaments. Its matrix of cells and ligaments are completely repeatable, regular and uniform throughout the entirety of the medium. These porous media have good thermal conductivity and structure integrity. It is rigid, highly porous and permeable and has a controlled density or ceramic per unit volume. Density of useful media for this invention varies from 5 to 90%, preferably from 30 to 50% for a combination of high permeability and thermal conductivity. Cell size can be from 5 to 150, preferably from 20 to 60 ppi (pores per inch) that has mean pore size from 5 mm to 0.12 mm, preferably from 1 to 0.3 mm. These porous media have high surface areas to volume ratio ranging from 10 to 80 cm²/cm³, thus compact reactors be fabricated for this invention. Porous Aluminum Oxide, preferably Silicon Carbide provided by Pyrotech Inc. are useful for this invention. Porous reactor of monolithic entity that has low heat-contact resistance between its heating element and heating body (porous ceramic) is useful for this invention.

When porous heater bodies are used, the inside diameter of pores should range from 0.01 to 5 mm, preferably 0.5 to 3 mm. In principle, when the inside diameter, Φi of these pore is less than the mean-free-path (“MFP”) of the precursors, more collision between the precursors and inside surfaces of the heater bodies can be expected. The MFP can be easily calculated by most engineers who are skillful in the state of art, thus needs no additional description here. However, when the pore size is too small, excess surface areas in gas flow or diffusion direction can generate too many collisions between precursors or their reaction products with the heater bodies inside the reactor. When pore sizes are much smaller than the MFP of these chemicals, forward diffusion of these chemicals can be impeded (“Gas Choking”) and coke formation becomes a serious problem under high reactor temperatures. Gas choking from a reactor can be detected when reaction products, that normally have smaller molecular weight than precursors, start to accumulate inside the reactor or condense right outside the reactor. For example, when precursor (IV) was used, yellow bromine gas was visible at the exit of a reactor that was comprised of one 30 ppi-SiC disks of one inch long, and when the reactor was heated to 450° C. More serious “gas-choking” was also observed when more than two pieces of the 30 ppi-porous disks were used. In this case, bromine was observed even at the entrance of the reactor due to back diffusion.

Gas choking of reactive intermediates or other reaction products inside the reactor can create excess coke formation due to long exposure of these chemicals at high temperature, and should be avoided during the designing of the reactor. One way to avoid this is a multiple-zone heater design, for instance, having a preheating and a cracking zone. Inside a preheating zone, the precursors will have limited conversion to intermediates due to a lower zone temperature. To avoid bi-molecular collision of intermediates during pre-heating, the partially pressure of the intermediates should be kept below few mTorrs. Once the precursors in the pre-heater reaching to a desirable temperature and pressure, the heated precursors can then be quickly released into a second heating zone for cracking. Using this two-zone heater, the cracking efficiency can be largely increase, but avoid excess carbon formation inside the reactor. By reducing heating path and temperature variation in the cracking zone of a reactor, chemical conversion efficiency can be maximized with lower amounts of carbon formation. Thus, when a multiple-zone reactor is used, the heater bodies in the pre-heating zone should consist of smaller pores, whereas the cracking zone should use bigger pores. To prevent intermediates from gas collision and achieving sufficient feed rate, Fi should be equal or 2 to 3 times higher than the MFP at the cracking zone of the reactor. thermal reactor consists of large number of smaller pores can be fabricated from ceramic such as, Al₂O₃, surface fluorinated Al₂O₃, Silicon Carbide, Silicon Nitride and Aluminum Nitride.

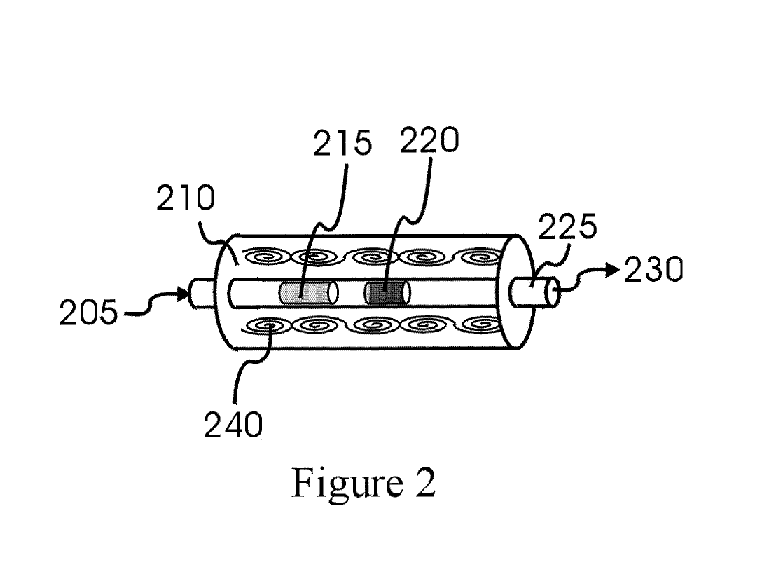

Preferred Reactor Designs: The thermal reactor can be in any shape or configuration as long as its temperature variation, dTr and pore size and surface area meeting the requirements mentioned in the above. The reactor shown in the FIG. 2 illustrates applications of the above teachings. The thermal reactor contains a precursor inlet 205, and a reactive intermediate outlet 230. When an IR heater 240 is used, the inside wall 225 of the thermal reactor should use an IR transparent material such as quartz, so that radiation can reach the precursor material inside of thermal reactor. Additionally, the inside wall 225 should be surrounded by an insulation jacket 210. The inside heater bodies 215 and 220 can be constructed using IR absorbing ceramic, especially porous ceramic such as SiC, Aluminum Nitride and Aluminum oxide, preferably SiC and Silicon Nitride. These porous ceramic heater bodies are spaced inside the reactor to create an alternating heating 215, 220, and mixing zones, inside the reactor as shown in FIG. 2 for a cross-section view. The heater bodies 215, and 220 are porous ceramic heater bodies. Preferably, the pore size of 215 is less than MFP, whereas the pore size of 220 is larger than MFP. Normally the heater body 215 is longer to insure sufficient preheating before cracking at heater body 220. Therefore, porous SiC or Silicon Nitride at 30 to 80 ppi, preferably 30 to 40 ppi or higher can be used in the preheating zone, 215. Porous ceramic from 20 to 25 ppi can be used in cracking zone 220.

The above design can ensure that intermediates and leaving groups, will not easily diffuse back into the preheating zone, or become trapped in between the preheating zone and the cracking zone. This is because the molecular mass of these resulting products are smaller and are at higher temperature, thus their MFP are much larger than the precursors in the preheating zone. Since the preheating zone 215 has smaller pore size, back diffusion of these smaller products will be inhibited. For instance, when a ⅞′ thick of porous Ceramic disk with 30 ppi was used inside the above reactor, back diffusion of bromine occurred, when the precursor (IV) was employed for preparation of thin films. The back-diffusion of reaction products was evident when bromine was found at the entrance of the reactor. On the another hand, if the 30 ppi disk is reduce to about ½ thick, or a 20 ppi disk of ⅞″ long thickness was used, back-diffusion of reaction products can be avoid under similar conditions.

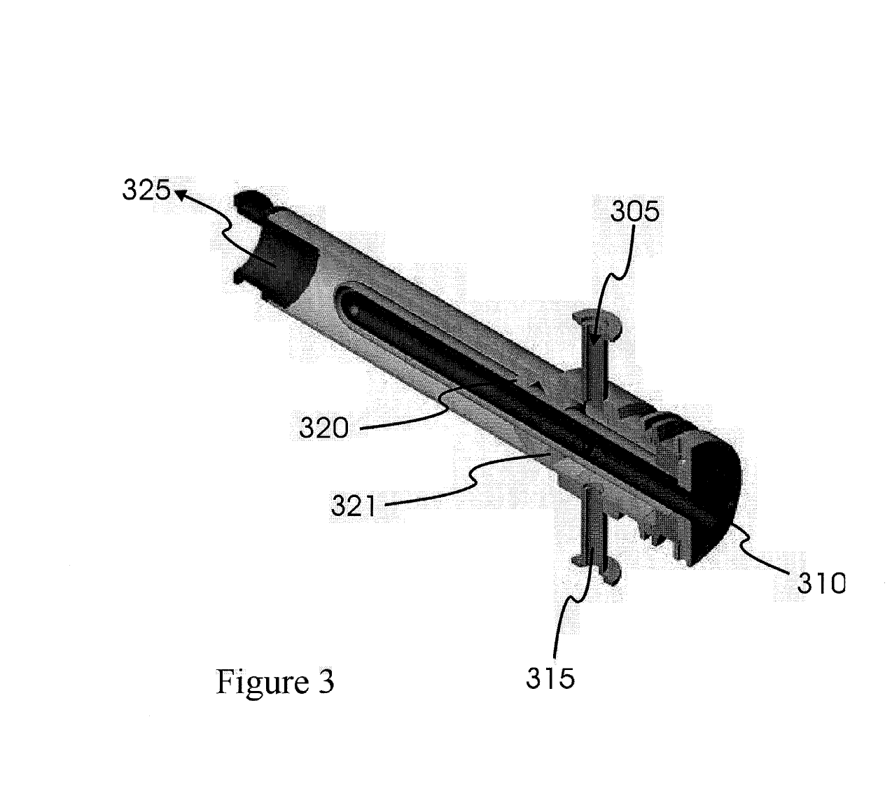

Alternatively, a double-wall quartz tube can be used in conjunction with both inner and outer IR heater as shown in the FIG. 3. Structure 305 is an inlet for precursor material, 310 is the inner IR heater, 325 is an outlet for intermediates and other products derived from reactions. The structural elements shown at 320 are porous heating bodies similar to 215 and 220 in the FIG. 2. Using both inner 310 and outer 330 IR heaters, one can improve the uniformity of temperature distribution over the cross-section of the porous heater bodies.

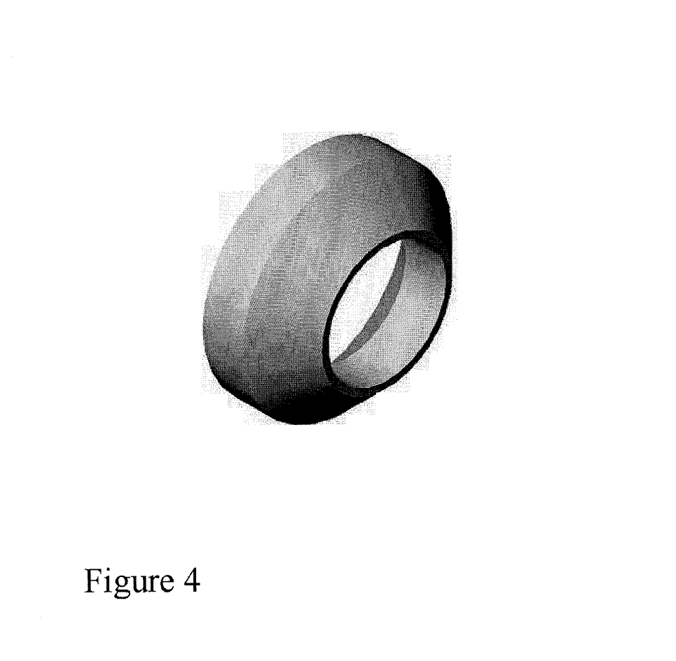

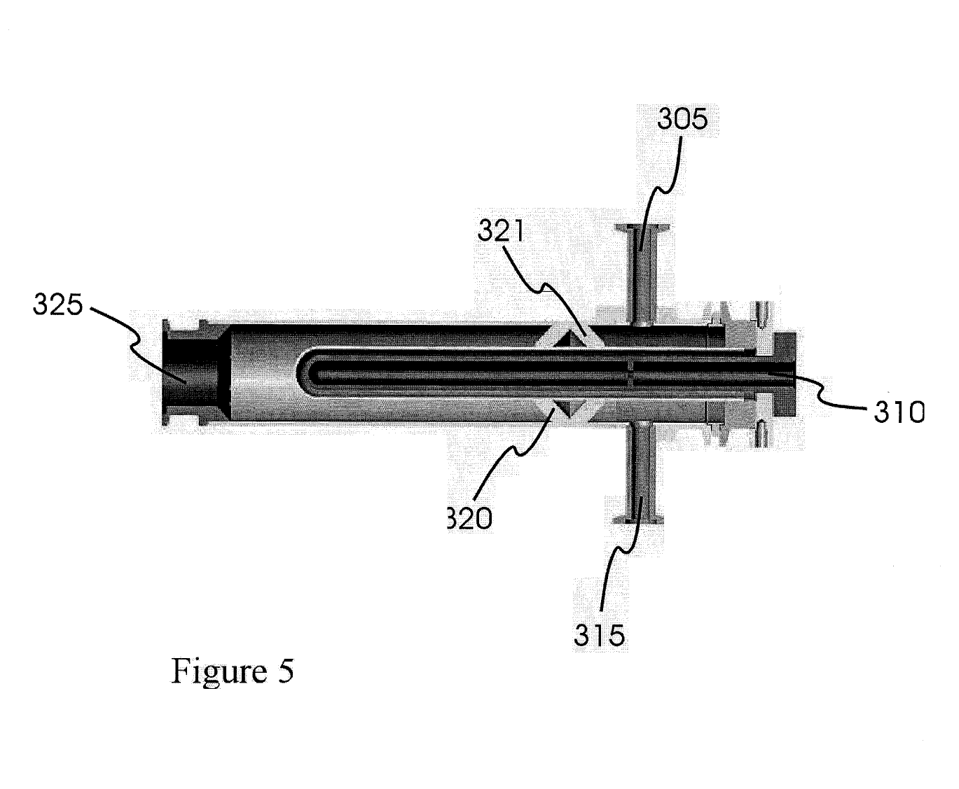

To further increase the surface areas for ,adsorption of IR without increasing the diffusion path-length for chemicals inside the reactor, the porous heating bodies, 320 and 321 were shaped as shown in the FIG. 4. FIG. 3 shows the cross-section of a cone-shaped heater body with a center hole for an inner IR heater. The 3-D views of these porous heating bodies are shown in FIG. 5, structures 320, and 321.

Alternatively, a resist heater can be used to heat a black body such as Silicon Carbide so the black body can generate IR in the ranges from 700 to 1200 cm−1. Therefore, the 310 in the FIG. 3 can be constructed from a resistive heater and SiC black body, instead of a tungsten lamp. In conjunction, the inside wall of the thermal reactor should be constructed using a IR transparent material so that radiation can reach the inside of the thermal reactor.

Still, the thermal reactor can also be constructed using a material that is not transparent to IR ranging from 700 to 1200 cm−1. For instance, the resist heater can be mounted directly onto the outside wall of the thermal reactor, while a black body such as SiC is inserted inside the thermal reactor. In this case, the inside wall of the double-wall tube in FIG. 3 can be eliminated. Alternatively, when the porous ceramic is used as heater bodies, microwave can be used to heat the media.

Alternatively, a thermal reactor of this invention can be heated by a resistive heater. In this case, the heater body needs sufficient thermal conductivity. Thus, some low density (<10-15%), porous media are not useful, instead, heater body can be constructed from solid heater elements such as small fins, closest packed balls, or small tubes. Ideally, a monolithic reactor wall and heating elements can reduce contact resistance for thermal conduction, thus heating fins are preferred. However, it is also know that most ceramic bodies are difficult to be manufactured into complex shape using alternative fins as heating element. In the present invention, a ceramic tube filled with ceramic spherical balls is used. Therefore, an alumina tube of a diameter range from 1 to 4 inches inside diameter is useful for the present invention. The spherical balls have a diameter ranging from 0.1 to 100 mm, preferably from 2 to 6 mm. Preferably, these spherical balls have the same diameter, thus they can be closest packed into the ceramic tube. The length of the ceramic balls filled reactor is at least 4 preferably 7 to 9 inches to provide sufficient low cracking temperature for the precursors of this invention. This thermal reactor is advantageous in view of providing high feed rate or deposition rate for the precursors of this invention. It can also lower the amounts of back diffusion and coke formation, comparing to the thermal reactors that consist of porous heater body.

In order to maximize heat transfer from the heater elements to the precursors, the reactor body can be constructed using a closely-packed-ball (“CPB”) design. There are several advantages of a CPB reactor. For example, the CPB reactor provides high packing density inside the reactor, which can store latent energy that is available for heating gaseous molecules. In contrast, passing gaseous precursor molecules through a reactor during deposition may cool of the porous media or fins. Additionally, the back-diffusion of reactive intermediates can be avoided when the flow rate of the precursor gaseous molecules is also increased due to the higher feed rate capabilities of a CPB reactor.

There are two known packing methods that can be found inside manufactured reactors with closely-packed-balls. The packing density (“φ”) of the “Symmetric Packing” method is equal to π/6 or 0.523. Additionally, the “Face Centered Packing” method allows a packing density (“φ”) that is equal to π/3\sqrt{2} or 0.74. Thus, ceramic balls as heating element offer a longer deposition time under the same feed rate, which is due to the high-density packing of these spherical balls (e.g. 52% to 74%). In a preferred embodiment of the present invention, the open space between the heater balls should be less than the mean free path (“MFP”) of the precursors. The preferred diameter for these ceramic balls ranges from about 1 mm to 20 mm, preferably from 4 to 7 mm. These ceramic balls have surface areas to volume ratio ranging from about 1 to 10 cm²/cm³, wherein compact reactors can be fabricated for this invention. The small balls for the TP Reactor can be fabricated from many different types of ceramic materials. However, ceramic materials with IR adsorbing properties such as, Al₂O₃, Alumina Carbide, surface fluorinated Al₂O₃, Silicon Carbide and Silicon Nitride. Alumina, Alumina Carbide and SiC, are preferred.

The Reactor Cleaning Subsystem (“RCS”): Because all thermal reactors need periodic cleaning to remove residual organic chemicals that become trapped inside the reactor, a thermal reactor needs to be equipped with a Reactor Cleaning Subsystem (“RCS”). The preferred RCS of the current invention is connected to the reactor and is by-passed to a sewage deposit tank or gas scrubber system. There are many different methods can be used to clean thermal reactor that contains organic residuals, some of these methods are:

i. A RCS can consist of a steam boiler and a pressurized nitrogen supply. The steam boiler can generate up to 1-5 psi, preferably from 5 to 10 psi of steam. The nitrogen pressure can be as high as 5 to 20 psi, or preferably 20 to 50 psi.

ii. A RCS can consist of a simple hot air blower or a oxygen tank. To clean the black carbon or organic residues inside the reactor 1-5 psi, or preferably from 5 to 20 psi of hot air or oxygen is injected into the reactor at high temperatures. The air or oxygen temperature should be within 200° C., and preferably within 100° C. of the reactor temperatures to prevent thermal shock and cracking of heater elements inside the reactor. This is especially important if the heater elements are made of ceramic or porous ceramic.

iii. Alternatively, a ceramic reactor can be also cleaned using oxidative plasma.

Additionally, to prevent film deposition inside the gas line between the thermal reactor and the deposition chamber, the gas line and chamber wall temperatures should be at least 25 to 30° C., preferably 30 to 50° C. It is important to note that the examples of the RCS systems are for a single deposition chamber for a single thermal reactor. One skilled in the art will appreciate that the design principles for the thermal reactor can be easily applied to industrial cluster tools that have multi-deposition chambers.

It should be appreciated by those of ordinary skill in the art that other embodiments may incorporate the concepts, methods, precursors, polymers, films, and devices of the above description and examples. The description and examples contained herein are not intended to limit the scope of the invention, but are included for illustration purposes only. It is to be understood that other embodiments of the invention can be developed and fall within the spirit and scope of the invention and claims. For example, all of the above discussions assume a single thermal Reactor per one deposition chamber; however, those who are skillful in tool designs can easily apply the above principles to make a larger thermal reactor for industrial cluster tools that have multi-deposition chambers.

### REFERENCES CITED

The following U.S. Patent documents and publications are incorporated by reference herein.

### U.S. PATENT DOCUMENTS

U.S. Pat, No. 3,268,599 issued in August of 1966 with Chow et al. listed as inventors.

U.S. Pat. No. 3,274,267 issued in September of 1966 with Chow listed as inventors.

U.S. Pat. No. 3,342,754 issued in September of 1967 with Gorham listed as inventors.

U.S. Pat. No. 5,268,202 issued in December of 1993 with You et al. listed as inventors.

U.S. Pat. No. 6,140,456 issued in October of 2000 with Foggiator et al. listed as inventors.

U.S. patent application Ser. No. 09/925,712 filed in August of 2001 Lee et al. listed as inventors.

U.S. patent application Ser. No. 10/029,373 filed in December of 2001 Lee et al. listed as inventors.

U.S. patent application Ser. No. 10/028,198 filed in December of 2001 Lee et al. listed as inventors.

U.S. patent application Ser. No. 10/116,724, filed on Apr. 4, 2002, and entitled “Chemically and Electrically stabilized Polymer Films” with Lee et al. listed as inventors.

U.S. patent application Ser. No. 10/115,879 filed in Apr. 4, 2002, and entitled “UV Reactor for Transport polymerization” with Lee et al. listed as inventors.

U.S. patent application Ser. No. 10/125,626 filed in Apr. 17, 2002, and entitled “Multi-stage-heating Thermal reactor for transport Polymerization” with Lee et al. listed as inventors.

U.S. patent application Ser. No. 10/126,919 filed in Apr. 19, 2002 entitled “Process Modules for transport polymerization of low ∈ thin films” with Lee et al. listed as inventors.

### OTHER REFERENCES

Chung J. Lee, “Transport Polymerization of Gaseous Intermediates and Polymer Crystals Growth”, J. Macromol. Sci-Rev. Macromol. Chem., C16 (1), 79-127 (1977-78), pp79-127)

Lu et al., J.Mater.Res.Vol,14(1), , p246-250, 1999; Plano et al., MRS Symp. Proc. Vol.476, p213-218, 1998

Peng Zou et al., “Quantum Yields and Energy Partitioning in the UV Photodissociation of Halon 2402)”,Jour. of Chem.Phys. Vol 113, No.17, P 7149 (2000).

Selbrede, et al., Characterization of Parylene-N Thin Films for Low Dielectric Constant VLSI Applications, February 10-11, 1997, DUMIC Conferece, 1997 ISMIC—222D/97/0034, 121-124.

Streitweissser, A, et al “Introduction to Organic Chemistry”, Appendix II. UC Berkeley Press (1992).

Wang, et al., Parylene-N Thermal Stability Increase by Oxygen Reduction-Low Substrate Temperature Deposition, Preannealing, and PETEOS Encapsulation, February 10-11, 1997, DUMIC Conference, 1997 ISMIC—222D/97/0034, 125-128.

Wary, et al., Polymer Developed to be Interlayer Dielectric, Semi-Conductor International, 211-216, June 1996.

Wunderlich et al., Jour. Polymer. Sci. Polymer. Phys. Ed., Vol. 11, (1973), pp 2403-2411; ibid, Vol. 13, (1975), pp1925-1938.

What is claimed is:

1. A thermal reactor for a transport polymerization (“TP”) process module that is useful for making a thin film from a precursor, the thermal reactor comprising:
(a) a vacuum vessel with a precursor-gas-inlet for receiving the precursor, and a gas-outlet for discharging an intermediate from the thermal reactor;
(b) a thermal source to crack the precursor, wherein the thermal source is in direct or indirect connection with the vacuum vessel;
(c) a heater body within the vacuum vessel to transfer energy to the precursor; and
(d) a thermal couple to regulate the temperature of the thermal source.

2. The thermal reactor of claim 1, further comprising a reactor cleaning subsystem (“RCS”) inlet on the vacuum vessel for receiving a cleaning gas.

3. The thermal reactor of claim 1, further comprising an insulation jacket surrounding the thermal reactor.

4. The thermal reactor of claim 1, wherein the precursor material has a general chemical structure: 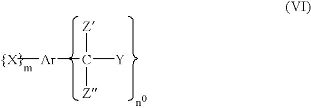
wherein
n⁰ or m is individually zero or an integer, and (n⁰+m) comprises an integer of at least 2 but no more than a total number of sp²C—X substitution on the aromatic-group-moiety (“Ar”),
Ar is an aromatic or a fluorinated-aromatic group moiety,
Z′ and Z″ are similar or different, and individually a hydrogen, a fluorine, an alkyl group, a fluorinated alkyl group, a phenyl group or a fluorinated phenyl group;
X is a first leaving group, and individually a —COOH, —I, —NR₂, —N⁺R₃, —SR, —SO₂R, wherein R is an alkyl, a fluorinated alkyl, aromatic or fluorinated aromatic group, and
Y is a second leaving group, and individually a —Cl, —Br, —I, —NR₂, —N⁺R₃, —SR, —SO₂R, or —OR, wherein R is an alkyl, a fluorinated alkyl, aromatic or fluorinated aromatic group

5. The thermal reactor of claim 4, wherein a leaving group bonding energy between the leaving group (“(BE)_{L}”) and a core group of the precursor is less than 85 Kcal/Mole, and the (BE)_{L} is at least 25 Kcal/Mole lower than a bonding energy of a next weakest chemical bond energy (“(BE)_{c}”) present in the precursor.

6. The thermal reactor of claim 4, wherein a temperature variation (“dTr”) is equal to, or less than 5 times a differential bond energy (“dBE”) expressed as Kcal/mole, wherein dBE=(BE)_{C}-(BE)_{L}, and (BE)_{L} is a leaving group bonding energy of the desired leaving group, and (BE)_{c} is a bonding energy of a next weakest chemical bond energy that present in the precursor.

7. The thermal reactor of claim 4, wherein the first or second leaving group is a halide.

8. The thermal reactor of claim 7, wherein the halide is selected from a group consisting of Br, I, and Cl.

9. The thermal reactor of claim 1, wherein the thermal source is selected from a group consisting of an infra red heater, an irradiation heater, a thermal heater, a plasma heater, and a microwave heater.

10. The thermal reactor of claim 1, wherein the vacuum vessel has an internal volume of at least 20 cm³.

11. The thermal reactor of claim 1, wherein the vacuum vessel has an internal volume of at least 40 cm³.

12. The thermal reactor of claim 1, wherein the heater body has a total surface area of at least 300 cm².

13. The thermal reactor of claim 1, wherein the heater body has a total surface area of at least 500 cm².

14. The thermal reactor of claim 1, wherein the vacuum vessel is manufactured from an IR transparent material and has an inside heater element.

15. The thermal reactor of claim 14, wherein the IR transparent material is quartz or Pyrex glass.

16. The thermal reactor of claim 14, wherein the heater element can adsorb sufficient IR radiation to achieve uniform temperatures that range from 400° C. to 700° C.

17. The thermal reactor of claim 14, wherein the heating elements can adsorb sufficient IR radiation to achieve uniform temperatures that range from 480° C. to 600° C.

18. The thermal reactor of claim 1, wherein the heater body comprises a plurality of alternating heating zones and mixing zones.

19. The thermal reactor of claim 18, wherein the alternating heating zones have a spiral orientation.

20. The thermal reactor of claim 18, wherein the alternating heating zones comprise multiple heating fins to increase the heating efficiency.

21. The thermal reactor of claim 20, wherein the multiple heating fins are spaced at a distance less than the mean free path (“MFP”) of a gas in the heating zone.

22. The thermal reactor of claim 1, wherein the heater body comprises a plurality of rows and columns of alternating heater fins.

23. The thermal reactor of claim 22, wherein the plurality of rows and columns of alternating heater fins are spaced at a distance less than the mean free path (“MFP”) of a gas in the heating region.

24. The thermal reactor of claim 1, wherein the heater body comprises spherical closely packed balls (“CPB”).

25. The thermal reactor of claim 24, wherein the CPB comprise a diameter that ranges from 0.5 mm to 10 mm.

26. The thermal reactor of claim 24, wherein the CPB comprise a diameter that ranges from 3 mm to 5 mm.

27. The thermal reactor of claim 24, wherein the CPB are constructed from materials selected from a group consisting of ceramic, silicon carbide, and alumina carbide.

28. The thermal reactor of claim 24, wherein the CPB are packed with a symmetric packing method.

29. The thermal reactor of claim 24, wherein the CPB are packed with a face centered packing method.

30. The thermal reactor of claim 24, wherein the CPB are packed with a packing density (“φ”) in the range from about 50% to about 74%.

31. The thermal reactor of claim 31, wherein the packing density (“φ”) have open space between the heater balls that is less than the mean free path (“MFP”) of the precursor material, wherein the MFP is in a range from about 1 mm to about 20 mm.

32. The thermal reactor of claim 1, wherein the heater body comprises a plurality of alternating heating elements and mixing zones, and wherein the alternating heating elements are on a standoff of the heater body arranged in a spiral configuration relative to a direction of overall flow from gaseous precursors in the thermal reactor.

33. The thermal reactor of claim 32, wherein the plurality of alternating heating elements are manufactured from ceramic materials resistant to halogen corrosion at temperatures in a range of 300° C.-700° C.

34. The thermal reactor of claim 32, wherein the plurality of alternating heating elements consists of porous ceramic disks.

35. The thermal reactor of claim 32, wherein the plurality of alternating heating elements consists of ceramic disks with small holes.

36. The thermal reactor of claim 32, wherein the plurality of alternating heating elements consist of ceramic fins.

37. The thermal reactor of claim 1, wherein the heater body is heated to a temperature of in the range of about 480° C. to about 600° C.

38. A thermal reactor for a transport polymerization (“TP”) process module that is useful for making a thin film from a precursor, the thermal reactor comprising:
(a) a ceramic vacuum vessel with a precursor-gas-inlet for receiving the precursor, a reactor cleaning subsystem (“RCS”) inlet on the ceramic vacuum vessel for receiving a cleaning gas, and a gas-outlet for discharging an intermediate from the thermal reactor;
(b) a thermal source for cracking the precursor;
(c) a heater body within the ceramic vacuum vessel to transfer energy to the precursor;
(d) a thermal couple to regulate the temperature of the thermal source; and
(e) an insulation jacket surrounding the thermal reactor.

39. The thermal reactor of claim 38, wherein the precursor material has a general chemical structure: 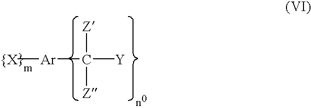
wherein
n⁰ or m is individually zero or an integer, and (n⁰+m) comprises an integer of at least 2 but no more than a total number of sp²C—X substitution on the aromatic-group-moiety (“Ar”),
Ar is an aromatic or a fluorinated-aromatic group moiety,
Z′ and Z″ are similar or different, and individually a hydrogen, a fluorine, an alkyl group, a fluorinated alkyl group, a phenyl group or a fluorinated phenyl group;
X is a first leaving group, and individually a —COOH, —I, —NR₂, —N⁺R₃, —SR, —SO₂R, wherein R is an alkyl, a fluorinated alkyl, aromatic or fluorinated aromatic group, and
Y is a second leaving group, and individually a —Cl, —Br, —I, —NR₂, —N⁺R₃, —SR, —SO₂R, or —OR, wherein R is an alkyl, a fluorinated alkyl, aromatic or fluorinated aromatic group

40. The thermal reactor of claim 39, wherein a leaving group bonding energy between the leaving group (“(BE)_{L}”) and a core group of the precursor is less than 85 Kcal/Mole, and the (BE)_{L} is at least 25 Kcal/Mole lower than a bonding energy of a next weakest chemical bond energy (“(BE)_{c}”) present in the precursor.

41. The thermal reactor of claim 39, wherein a temperature variation (“dTr”) is equal to, or less than 5 times a differential bond energy (“dBE”) expressed as Kcal/mole, wherein dBE=(BE)_{C}-(BE)_{L}, and (BE)_{L} is a leaving group bonding energy of the desired leaving group, and (BE)_{c} is a bonding energy of a next weakest chemical bond energy that present in the precursor.

42. The thermal reactor of claim 39, wherein the first or second leaving group is a halide.

43. The thermal reactor of claim 42, wherein the halide is selected from a group consisting of Br, I, and Cl.

44. The thermal reactor of claim 38, wherein the thermal source comprises a resistive heater.

45. The thermal reactor of claim 38, wherein the ceramic vacuum vessel has an internal volume of at least 20 cm³.

46. The thermal reactor of claim 38, wherein the ceramic vacuum vessel has an internal volume of at least 40 cm³.

47. The thermal reactor of claim 38, wherein the heater body has a total surface area of at least 300 cm².

48. The thermal reactor of claim 38, wherein the heater body has a total surface area of at least 500 cm².

49. The thermal reactor of claim 38, wherein the ceramic vacuum vessel is manufactured from ceramic material selected from a group consisting of silicon nitride, aluminum nitride, aluminum oxide, aluminum carbide and silicon carbide.

50. The thermal reactor of claim 38, wherein the ceramic vacuum vessel further comprises an inside heating element.

51. The thermal reactor of claim 38, wherein the heater body can adsorb sufficient heat energy to achieve uniform temperatures in the range of 400° C. to 700° C.

52. The thermal reactor of claim 38, wherein the heater body can adsorb sufficient heat energy to achieve uniform temperatures in the range of 480° C. to 600° C.

53. The thermal reactor of claim 38, wherein the heater body comprises a plurality of alternating heating zones and mixing zones.

54. The thermal reactor of claim 53, wherein the alternating heating zones comprise a spiral orientation.

55. The thermal reactor of claim 53, wherein the alternating heating zones comprise multiple heating fins to increase the heating efficiency.

56. The thermal reactor of claim 55, wherein the multiple heating fins are spaced at a distance less than the mean free path (“MFP”) of a gas in the heating zone.

57. The thermal reactor of claim 38, wherein the heater body comprises a plurality of rows and columns of alternating heater fins.

58. The thermal reactor of claim 57, wherein the plurality of rows and columns of alternating heater fins are spaced at a distance less than the mean free path (“MFP”) of a gas in the heating region.

59. The thermal reactor of claim 38, wherein the heater body comprises spherical closely packed balls (“CPB”).

60. The thermal reactor of claim 59, wherein the CPB comprise a diameter that ranges from 0.5 mm to 10 mm.

61. The thermal reactor of claim 59, wherein the CPB comprise a diameter that ranges from 3 mm to 5 mm.

62. The thermal reactor of claim 59, wherein the CPB are constructed from materials selected from a group consisting of ceramic, silicon carbide, and alumina carbide.

63. The thermal reactor of claim 59, wherein the CPB are packed with a symmetric packing method.

64. The thermal reactor of claim 59, wherein the CPB are packed with a face centered packing method.

65. The thermal reactor of claim 59, wherein the CPB are packed with a packing density (“φ”) in the range from about 50% to about 74%.

66. The thermal reactor of claim 65, wherein the packing density (“φ”) have open space between the heater balls that is less than the mean free path (“MFP”) of the precursor material, wherein the MFP is in a range from about 1 mm to about 20 mm.

67. The thermal reactor of claim 38, wherein the heater body comprises a plurality of alternating heating elements and mixing zones, and wherein the alternating heating elements are on a standoff of the heater body arranged in a spiral configuration relative to a direction of overall flow from gaseous precursors in the thermal reactor.

68. The thermal reactor of claim 67, wherein the plurality of alternating heating elements are manufactured from ceramic materials resistant to halogen corrosion at temperatures in a range of 300° C.-700° C.

69. The thermal reactor of claim 67, wherein the plurality of alternating heating elements consists of porous ceramic disks.

70. The thermal reactor of claim 67, wherein the plurality of alternating heating elements consists of ceramic disks with small holes.

71. The thermal reactor of claim 67, wherein the plurality of alternating heating elements consist of ceramic fins.

72. The thermal reactor of claim 38, wherein the heater body is heated to a temperature of in the range of about 480° C. to about 600° C.

73. A method of cleaning an organic residue inside the thermal reactor of claim 2 or claim 38 using a reactor cleaning subsystem (“RCS”) comprising:
(a) heating the heater body to a desired temperature with an energy source;
(b) introducing a heated gas into the thermal reactor through the RCS gas inlet;
(c) burning the organic residue with the heated gas to give an oxidized gas; and
(d) discharging the oxidized gas from the reactor.

74. The method of claim 73, wherein an inside temperature of the thermal reactor is at least 400° C. during the RCS cleaning process.

75. The method of claim 73, wherein the heated gas supply is maintained at a temperature within at least 100° C. of a temperature in the thermal reactor to prevent thermal shock or cracking of the heater bodies inside the thermal reactor.

76. The method of claim 73, wherein the heated gas supply is pressurized oxygen.

77. The method of claim 76, wherein the pressurized oxygen is in the range from about 1 to 20 psi.

78. The method of claim 73, wherein the heated gas supply is pressurized air.
